(19) United States
(12) Patent Application Publication
(10) Pub. No.: US 2006/0063388 A1
(43) Pub. Date: Mar. 23, 2006

(54) Method for using a water vapor treatment to reduce surface charge after metal etching

(75) Inventors: Yao-Jung Yang, Jhonghe City (TW); Ming-Shuo Yen, Jhubei City (TW); Yi-Ming Wang, Hsinchu City (TW); Yi-Ping Pan, Taipei City (TW)

Correspondence Address: HAYNES AND BOONE, LLP, 901 MAIN STREET, SUITE 3100, DALLAS, TX, 75202, US

(73) Assignee: Taiwan Semiconductor Manufacturing Company, Ltd., Hsin-Chu (TW)

(21) Appl. No.: 10/947,859

(22) Filed: Sep. 23, 2004

(51) Int. Cl. H01L 21/302

(52) U.S. Cl. 438/745

(57) ABSTRACT

The present disclosure provides a method for reducing or eliminating residual surface charge from a wafer during a semiconductor fabrication process. Because metal etching and photo resist ashing may result in a surface charge, performing a wet cleaning process directly after the ashing may increase corrosion to metal surfaces. This corrosion may be caused by an electro-chemical reaction that occurs between the surface charge and a solvent used in the wet cleaning process. To prevent this, the present disclosure introduces a water vapor treatment between the ashing and the wet cleaning processes. The water vapor treatment, which may be performed in-situ, provides an electrically neutral path that carries the surface charge from the surface of the wafer to electrical ground. By reducing or eliminating the surface charge, the water vapor treatment lessens or prevents corrosion to metal areas.

### BACKGROUND

The present disclosure relates generally to the fabrication of semiconductor devices, and more particularly, to a method for using a water vapor treatment to reduce surface charge after metal etching.

An integrated circuit (IC) is formed by creating one or more devices (e.g., circuit components) on a substrate using a fabrication process. Technological advances in IC materials and design have produced generations of ICs where each generation is smaller and more complex than the previous generation. However, these advances have increased the complexity of processing and manufacturing ICs and, for these advances to be realized, similar developments in IC processing and manufacturing have been needed.

One limitation in IC fabrication is in the area of metallization, which includes the growth, formation, and/or deposition of a conducting material (e.g., a metal film). The metallization of IC devices generally requires that certain parameters be maintained with respect to metal film quality and electrical reliability. For example, defects and particles introduced during a film deposition process may reduce device electrical yield and reliability. Furthermore, defects that cannot be removed during later processing steps may cause a short between metal lines. Other failure modes, such as surface charging, may induce failures in devices fabricated below a metallization layer.

Surface charging (e.g., the accumulation of excess electrical charge at the surface of a semiconductor substrate) that is induced by a plasma-based process is known as plasma-induced charging. Such charging may directly damage portions of IC devices, such as a gate oxide of a field effect transistor, and may also cause charge to accumulate on metal surfaces, which may induce process failures in subsequent processing steps. Since the discovery of plasma-induced surface charging as a failure mode, various methods for reducing such surface charging have been implemented. However, as semiconductor geometries have decreased and as new fabrication processes have been implemented, existing methods for reducing plasma-induced surface charging have decreased in effectiveness.

Plasma-induced surface charging, for example, may cause damage in the case of residual H₂O on Si₃N₄ films. Charging may also occur at non-localized regions on a semiconductor substrate due to plasma non-uniformities, where the plasma potential and plasma densities vary from the bulk plasma characteristics. The local non-uniformities may result in excess charge that may damage an IC device. This may be of particular concern during subsequent processing, such as during the dry etching of dielectrics lying close to metal-oxide semiconductor field effect transistors (MOSFETs) or other electrical structures.

Plasma-induced surface charging may also occur while dry etching metals, causing unwanted reactions to occur during the post processing of a semiconductor wafer in a chemical bath. This problem may be exacerbated when H₂O resides on the surface of an etched metal, such as an Al/Cu metal line coupled with a tungsten via or contact. The plasma-induced charging of the surface may result in positively charged ions that are able to catalyze a galvanic reaction when the substrate is dipped into a solvent (such as those distributed by EKC Technology, Inc.) to remove amine residues.

The solvent dip may act to neutralize and remove metal ion contamination and surface-absorbed cationic and anionic contaminants, as well as reduce metal corrosion on very large scale integrated (VLSI) and ultra large scale integrated (ULSI) structures. The solvent chemistry may be specifically targeted to amine-based chemistries, such as residues of photo resist. Typically, solvents targeted to amine-based chemistries are used for post etch residue removal from vias and metal lines. However, although such solvents are generally effective, they may cause metal corrosion if the amine-based solvent residues are not removed thoroughly, particularly with aluminum, copper, titanium, and other metals.

Also, in conjunction with the plasma-induced surface charge, galvanic corrosion may occur. The use of the solvent for removal of post oxygen plasma is in part due to the use of metal organic precursors in the formation of metal materials such as TiN, TiW, Ti, TiSi, WSi, W, and the like. The use of these metal materials may produce organometallic material by-products during plasma etching, either intentionally or unintentionally, which may render the cleaning incomplete when utilizing existing commercially available stripping and cleaning products. In particular, it has been found that the residue remaining on the substrate metal surface after removal of the resist by an oxygen plasma ashing process may have changed from an organometallic material to a corresponding oxide, such as TiO₂, which is chemically inert to mild alkaline strippers. It is this residue in the vicinity of the via that should be removed with a specialty stripper such as the solvent. However, as previously described, the solvent may react with the induced surface charge from the plasma ashing process to cause galvanic corrosion.

Accordingly, what is needed is an improved method for removing the surface charge that accumulates during a semiconductor fabrication process.

### SUMMARY

In one embodiment, a method is provided for preventing corrosion of a conductive layer during semiconductor fabrication, wherein the conductive layer is at least partially covered by a resist layer. The method comprises etching the conductive layer using a dry etch process, removing the resist layer using a dry process, performing a water vapor treatment to remove residual surface charge from the conductive layer after removing the resist layer, and performing a wet cleaning process following the water vapor treatment.

### BRIEF DESCRIPTION OF THE DRAWINGS

FIG. 1 is a flow chart illustrating an exemplary method for using a water vapor treatment to reduce a residual surface charge during a semiconductor fabrication process

FIG. 2 is a cross-sectional view of an exemplary substrate on which the method of FIG. 1 may be performed.

FIG. 3 is a cross-sectional view of the substrate of FIG. 2 illustrating a residual surface charge.

FIG. 4 is a cross-sectional view of the substrate of FIG. 3 undergoing a water vapor treatment to reduce the residual surface charge.

### DETAILED DESCRIPTION

The present disclosure relates generally to the fabrication of semiconductor devices, and more particularly, to a method for using a water vapor treatment to reduce surface charge after metal etching. It is understood, however, that the following disclosure provides many different embodiments or examples. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

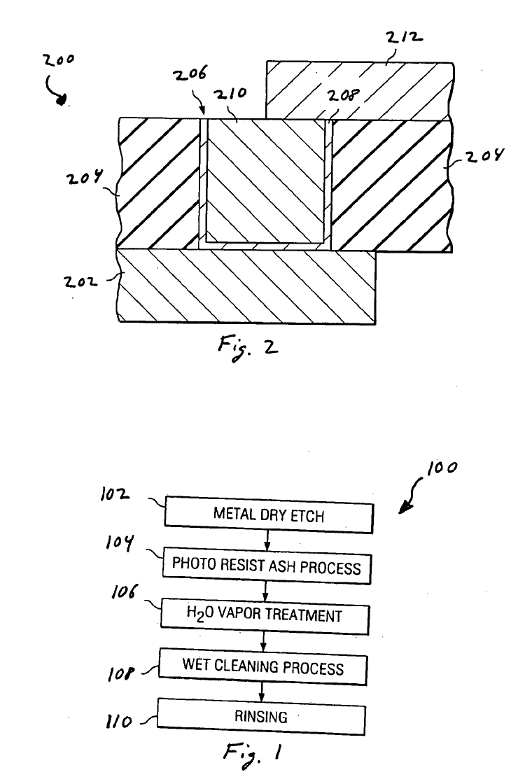

Referring to FIG. 1, a method 100 may be used to reduce or eliminate an electrical surface charge that may occur during an IC fabrication process. By reducing or eliminating the surface charge, galvanic corrosion and other undesirable effects associated with the surface charge may be prevented or minimized. In the present example, the method 100 is described in conjunction with the fabrication of a metal via and interconnects on a semiconductor substrate, which is described below in greater detail with reference to FIG. 2. However, it is understood that the method 100 may be used in conjunction with many different types of ICs, as well as different IC structures, layers, and/or fabrication steps.

Referring now to FIG. 2, a cross-section of an exemplary IC 200 on a semiconductor wafer is illustrated. The IC 200 includes a substrate (not shown), on which may be formed a plurality of different layers. The layers may include metal layers, dielectric layers, and other layers that are used to form basic device structures on the substrate. For example, a metallization layer, such as a metal interconnect 202, may be formed on the substrate. The metal interconnect 202 may be fabricated using several different film deposition processes, such as chemical vapor deposition (CVD), plasma enhanced chemical vapor deposition (PECVD), electro-chemical deposition, physical vapor deposition, sputtering, or any other suitable method. Additional processing steps may include lithographic patterning and etching of the metal interconnect 202. The metal interconnect 100 may comprise a barrier metal and a bulk metal, and may be fabricated from any assortment of conducting elemental materials and alloys.

A dielectric layer (or layers) 204 comprising one or more dielectric films may be deposited above the metal interconnect 202. The dielectric layer 204 may be formed by CVD, PECVD, spin coating, or any other suitable method. In some embodiments, the dielectric layer 202 may be doped with a material such as boron and/or phosphate to prevent sodium ions from penetrating through the layer 202 and causing damage to underlying layers. An exemplary material that may be used for the dielectric layer is TEOS-oxide, or Tetrakis orthsilicate, which may be deposited by CVD or PECVD.

A via 206 may be fabricated in the dielectric layer 204 using a chemical (wet) etch or a dry etch to provide an electrical connection through the dielectric layer 204 to the metal interconnect 202. In VLSI and ULSI structures, where patterned features (e.g., vias and contacts) may be less than 1 μm, a plasma etch may be the preferred method for forming the vias due to the plasma etch's ability to provide a relatively high anisotropic etch profile. The via 206 may then be filled by a metal barrier 208. The metal barrier 208, which may be formed using CVD, PECVD, spin coating, or another suitable method, may comprise a metal such as titanium or titanium nitride. Other barrier metals, such as tantalum nitride, may be employed for use with copper interconnects because of their increased adhesion abilities and their ability to prevent copper diffusion.

The metal barrier 208 inside the via 206 may coated or deposited with a metal film to form a plug 210. The plug 210 may comprise a combination of materials, such as tungsten and tungsten silicide, or may comprise a single material, such as tungsten. The plug 210 may also be formed using another metal, such as copper, through the process of electro-plating and/or copper CVD. The metal film used to create the plug 210 may be deposited by a selective or blanket deposition process over the metal interconnect 202 and dielectric layer 204. Selective deposition may increase the difficulty of the deposition process, as it may need special light treatment or the application of a material that promotes or prevents tungsten nucleation. The via 206 may also be filled by other appropriate materials that provide adequate step coverage and fill according to a desired feature geometry. A portion of the plug 210 that extends above the metal barrier 208 may be etched or polished down to an interface defined by the metal barrier 208 or the dielectric layer 204 using chemical mechanical polishing (CMP), plasma etching, or any other suitable method.

The plug 210 may be completely or partially covered by a second metallization layer, such as a metal interconnect 212. The metal interconnect 212 may be formed from a variety of different materials, such as a stacked layer of barrier films and a bulk metal film of copper and aluminum, and may be deposited as described with respect to the metal interconnect 202.

A layer of photo resist (not shown) may be deposited on the metal interconnect 212. If the metal interconnect 212 does not completely cover the dielectric layer 204 and/or via 206, the photo resist layer may also be deposited on one or both of those layers. As is known in the art, the photo resist layer enables a pattern to be formed during later etching of an underlying area. The photo resist may be negative or positive, depending on the particular fabrication process used.

Referring again to FIG. 1, in step 102, the metal interconnect 212 is etched according to the pattern defined by the photo resist layer. The etching process may be a dry or wet etch, and may be performed on metal interconnect 212 in a chamber that is a part of a cluster of process tools or is a separate process in a single process chamber. In the present example, the etch is a dry etch that is performed until an etch stop is reached. For example, the material forming the metal interconnect 212 may be etched down to an interface provided by a top portion of the plug 210 and the dielectric layer 204, or may be etched until a predetermined area of the plug 210 serving as an etch stop is exposed. A determination that the etch stop has been exposed may be made by using various end point detection methods, such as optical emission spectroscopy, laser diffraction, or other methods known by those skilled in the art.

In step 104, the photo resist layer may be stripped to remove the photo resist for later processing steps. In the present example, the photo resist layer is stripped using a plasma-based ashing process. The ashing process may be performed in-situ, and may occur in the same process chamber as the previous step or in a separate process chamber using a cluster of integrated tools. The ashing process may comprise a sequence of sub-process steps to remove the photo resist using plasma-enhanced reactions that generate ozone from oxygen and water. These sub-processes may include stabilizing the pressure of the chamber, adjusting a radio frequency (RF) or microwave plasma source, setting a step time, introducing process gasses, and pumping out or purging the effluents from the chamber. The process environment for the ashing process may include H₂O, oxygen, and an inert gas (e.g., nitrogen or a mixture of dried nitrogen and one or more of the noble Group VIII gases including He, Ne Ar, Kr, Xe, and Rn).

The ashing process may produce gases, such as CO, CO₂, and H₂O, that may be pumped out of the reactor through a vacuum system. It is understood that during the ashing process, the substrate may be heated separately, concurrently, or in any order. An elevated temperature may maintained while the substrate is in a vacuum environment to facilitate the ashing process of step 104. For example, with a process temperature maintained at 250° C., the O₂ and H₂O plasma may strip away the organic photo resist. Although the ashing process may be performed at a variety of pressures, a pressure of 2 torr is used for purposes of illustration. The process environment may be evacuated at a much lower pressure at the end and/or beginning of the process. It is understood that different combinations of valves and different mechanisms for controlling process parameters may be used to facilitate process design choices pertaining to different fabrications and/or different manufacturers of process equipment.

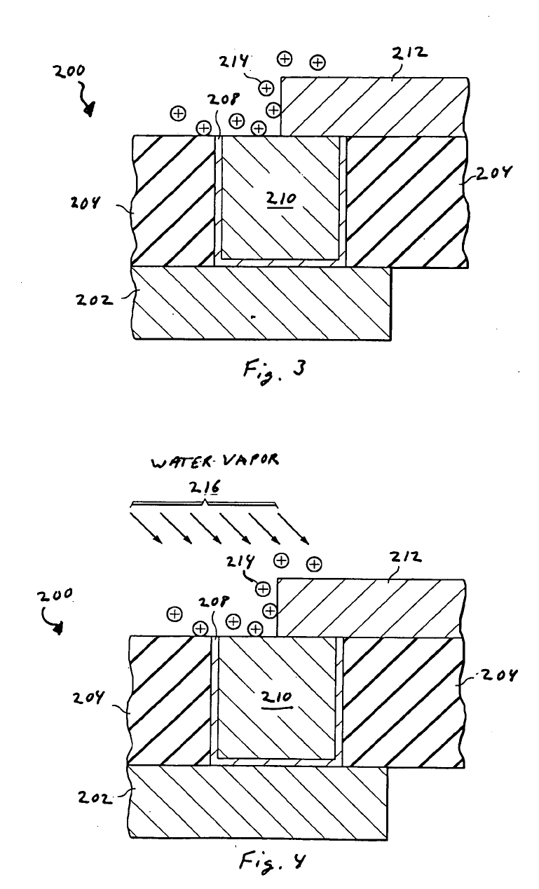

Referring now to FIG. 3, a residual, plasma-induced surface charge 214 may remain on the wafer after the ashing process. The residual surface charge 214 may be induced by the plasma used to strip the photo resist in the ashing process of step 104 when the built-up charge is not transported to electrical ground at the end of the plasma process. This positive residual surface charge 214 may occur on the surface of the wafer, especially in the vicinity of the metal interconnect 212 and via 206, and may cause corrosion or degradation of the metal and associated structures. Generally, in a standard fabrication process, the wafer would undergo a wet cleaning process (e.g., being dipped in a solvent) to remove the polymer or other photo resist residue that may remain following the ashing process. For example, the wafer may be dipped into a sink filled with a solvent and, with appropriate dipping times, temperatures, and solution concentrations, the polymer residues react with the solvent and are removed.

However, because of the residual surface charge 214, the wet cleaning process may cause corrosion due to an electro-chemical reaction between the charged wafer and the solvent. For example, tungsten migration or corrosion may occur in the via 206 as a result of a galvanic reaction governed by the equation:

$$W + \frac{2}{3} {O}_{2} + 2 {OH}^{-} \to {WO}_{4}^{2 -} + {H}_{2} {OE}_{0} = 1.9 V \qquad ( 1 )$$

where the anode and cathode of the reaction may be governed, respectively, by:

$$\begin{matrix}W + 8 {OH}^{-} \to {W O}_{4}^{2 -} + 4 {H}_{2} O + 6 {e}^{-} {E}_{0} = 1.5 V & ( 2 ) \\ \frac{2}{3} {O}_{2} + 3 H2O + 6 {e}^{-} \to 6 {OH}^{-} {E}_{0} = 0.4 V & ( 3 )\end{matrix}$$

This may result in, for example, dredging of the via 206, which may lead to increased resistance or failure. For purposes of illustration, the IC 200 may include 800,000 vias that should meet a certain resistivity level to be within desired design parameters. However, if any of the vias are dredged, the increased resistivity may cause the IC to fail a wafer access test.

In step 106 of FIG. 1 and with additional reference to FIG. 4, a water vapor treatment is performed on the wafer prior to performing a wet cleaning process. The water vapor treatment aids in reducing or eliminating the residual surface charge that remains after the ashing process of step 104. While the water vapor of the present illustration is H₂O, it is understood that water vapor, as used herein, may include other components. The electrically neutral water vapor 216 picks up the residual positive surface charge 214 and provides a pathway to electrical ground. Accordingly, the pathway created by the water vapor 216 carries the plasma-induced charge 214 from the surface of the wafer.

The water vapor treatment of step 106 may be performed either in-situ or ex-situ in the same or another process chamber. Process values may be selected for the water vapor treatment, including temperature, pressure, time period, and flow rate. For example, a temperature may be selected from a range of approximately 245° C. to 255° C., a pressure may be selected from a range of approximately 1.8 torr to 2.2 torr, a time period may be selected from a range of approximately five to twenty seconds, and a flow rate may be selected from a range of approximately 600 standard cubic centimeters per minute (sccm) to 700 sccm. For purposes of illustration, the water vapor treatment occurs at a temperature of approximately 250° C., a pressure of approximately 2 torr, a time period of approximately 15 seconds, and an H₂O flow rate of approximately 650 sccm. Furthermore, in the present example, no microwave or RF source is activated during the water vapor treatment. It is understood that other settings may be selected. Certain aspects of the water vapor treatment, such as the temperature, pressure, time period, and/or flow rate may be automatically controlled within the process chamber using, for example, computer instructions to operate a computer-controlled servo.

In step 108, the wafer undergoes a wet cleaning process. However, due to the previous water vapor treatment of step 106, galvanic corrosion and other degradation of metals on the wafer should be reduced or eliminated. For example, corrosion of the plug 210 should be minimized or eliminated since the residual surface charge needed for a galvanic reaction is no longer present during the wet cleaning process of step 108.

It is understood that other steps may be performed. For example, a water-rinsing process may be performed in step 110 in which the wafer is oriented vertically to ensure that the fringe of the wafer is cleaned. The wafer may then be dipped into deionized water to clean off the remaining solvent. Furthermore, the illustrated process steps may be followed by other steps (e.g., depositing and patterning additional metallization layers, post-etch cleaning, and depositing additional dielectric layers) until the IC 200 is fabricated.

A further advantage of the water vapor treatment is that the introduction of the water vapor 216, even in the absence of a residual surface charge 214, may provide excess moisture to the plug 110. This may enable more efficient cleansing by the solvent, or may act to prevent the accumulation of solvent amines in the plug 110. For example, solvents used in wet cleaning processes may cause corrosion of metal plugs if the solvent remains in contact with a metal plug for a certain period of time. Such corrosion may also occur if a rinsing process used to clean off the solvent is ineffective and residual solvent is left on the plug 110. This corrosion may not be observed for a relatively long period of time after subsequent processing, and may be discovered only during electrical testing when the plug 110 fails to effectively connect the device elements of the metal interconnect 202 to another metallization layer (e.g., the metal interconnect 212). This may result in device failure.

The present disclosure has been described relative to a preferred embodiment. Improvements or modifications that become apparent to persons of ordinary skill in the art only after reading this disclosure are deemed within the spirit and scope of the application. Specifically, treatment of the metal silicon-based surfaces as described above is not limited to a family of semiconductor devices and may be used to treat other metal silicon-based surfaces of any shape planar, curved, spherical, or three-dimensional. It is understood that several modifications, changes and substitutions are intended in the foregoing disclosure and in some instances some features of the invention will be employed without a corresponding use of other features. Accordingly, it is appropriate that the appended claims be construed broadly and in a manner consistent with the scope of the invention.

What is claimed is:

1. A method for preventing corrosion of a conductive layer during semiconductor fabrication, wherein the conductive layer is at least partially covered by a resist layer, the method comprising:
etching the conductive layer using a dry etch process;
removing the resist layer using a dry process;
performing a water vapor treatment to remove residual surface charge from the conductive layer after removing the resist layer; and
performing a wet cleaning process following the water vapor treatment.

2. The method of claim 1 wherein removing the resist layer includes using a plasma-based ashing process.

3. The method of claim 1 wherein performing the wet cleaning process includes dipping the conductive layer in a solvent.

4. The method of claim 1 wherein the water vapor treatment is performed in-situ.

5. The method of claim 1 further comprising selecting a temperature, a pressure, a time period, and a flow rate for the water vapor treatment.

6. The method of claim 5 further comprising selecting a temperature from a range of approximately 245 to 255° C.

7. The method of claim 6 wherein the temperature selected is 250° C.

8. The method of claim 5 further comprising selecting a pressure from a range of approximately 1.8 torr to 2.2 torr.

9. The method of claim 8 wherein the pressure selected is 2 torr.

10. The method of claim 5 further comprising selecting a time period from a range of approximately 5 seconds to 20 seconds.

11. The method of claim 10 wherein the time period selected is 15 seconds.

12. The method of claim 5 further comprising selecting a flow rate from a range of approximately 600 standard cubic centimeters per minute (sccm) to 700 sccm.

13. The method of claim 12 wherein the flow rate selected is 650 sccm.

14. The method of claim 5 further comprising selecting a temperature of approximately 250° C., selecting a pressure of approximately 2 torr, selecting a time period of approximately 15 seconds, and selecting a flow rate of approximately 650 sccm.

15. The method of claim 1 wherein performing the water vapor treatment includes:
creating a water vapor; and
creating an electrical pathway from the conductive layer to ground using the water vapor, wherein the residual surface charge passes through the water vapor to ground.

16. A method for preventing corrosion of a metal during semiconductor processing, the method comprising:
coating a photo resist layer on the metal to define a pattern;
stripping the photo resist layer after etching the metal;
performing an in-situ water vapor treatment to remove residual electrical charge remaining on the metal after the stripping; and
performing a wet cleaning process following the water vapor treatment.

17. The method of claim 16 further comprising etching the metal using a dry etch process.

18. The method of claim 16 wherein stripping the photo resist includes using a plasma-based ashing process.

19. The method of claim 18 wherein the plasma-based ashing process uses an oxygen-based plasma.

20. The method of claim 16 wherein performing the wet cleaning process includes dipping the metal in a solvent.

21. The method of claim 16 further comprising:
selecting a temperature for the water vapor treatment
selecting a pressure for the water vapor treatment;
selecting a time period for the water vapor treatment; and
selecting a flow rate for the water vapor treatment.

22. A system for performing a water vapor treatment during a semiconductor fabrication process, the system comprising:
at least one processing chamber;
at least one servo associated with the processing chamber; and
a plurality of computer instructions for controlling the at least one servo, the instructions including:
instructions for etching the metal layer using a dry etch process;
instructions for stripping a photo resist layer using a dry strip process;
instructions for performing a water vapor treatment to remove residual surface charge from the metal layer after stripping the photo resist; and
instructions for performing a wet cleaning process following the water vapor treatment.
